(19) United States
(12) Patent Application Publication
(10) Pub. No.: US 2006/0138438 A1
(43) Pub. Date: Jun. 29, 2006

(54) Method for manufacturing color element film-equipped substrate, color element film-equipped substrate, electro-optical device, and electronic device

(75) Inventor: Satoru Katagami, Haramura (JP)

Correspondence Address: GLOBAL IP COUNSELORS, LLP, 1233 20TH STREET, NW, SUITE 700, WASHINGTON, DC, 20036-2680, US

(73) Assignee: Seiko Epson Corporation, Shinjuku-ku (JP)

(21) Appl. No.: 11/300,392

(22) Filed: Dec. 15, 2005

(30) Foreign Application Priority Data
Dec. 27, 2004 (JP) 2004-375703

(51) Int. Cl. B41M 5/00; H01L 29/22; H01L 33/00

(52) U.S. Cl. 257/98; 428/195.1

(57) ABSTRACT

A method for manufacturing a color element film-equipped substrate includes: forming a bank, in which a first layer and a photo-curing second layer are laminated over a base, and parts of the first layer and the second layer are removed after exposing and developing the first layer and the second layer, with a remainder of the first layer and the second layer serving as a bank; applying a liquid material used for forming a color element film to a region demarcated by the bank; and forming a color element film by curing or solidifying the liquid material applied to the region. The first layer is soluble in a developing liquid during the developing. The second layer is soluble in the developing liquid but dissolves more slowly than the first layer does. The bank is formed with the width of the remainder of the second layer being greater than the width of the remainder of the first layer after the development.

### BACKGROUND

1. Technical Field

The present invention relates to a method for manufacturing a color element film-equipped substrate, to a color element film-equipped substrate, to an electro-optical device, and to an electronic device.

2. Related Art

It is known that an inkjet apparatus can be used to apply ink or another such liquid material to regions demarcated by banks formed on a base, and to form a color element film by curing or solidifying this material. For example, there is a known method for using an inkjet apparatus to form light emitting components arranged in a matrix in a matrix-type display device, or filter elements in a color filter substrate (see JP-A-2002-62422, for example).

For example, in JP-A-2002-62422, the banks that form the regions are formed so as to gradually and continuously taper in width toward the base, and the liquid repellency of the lower part of the banks with respect to the liquid material is lower than that of the upper part. The result is that when the liquid material is applied to the regions, it spreads out into every corner of the regions, and this prevents color unevenness or a decrease in contrast in the resulting color filter substrate.

The above-mentioned banks are manufactured by photolithography. More specifically, a single photoresist layer is formed on a base, and this photoresist layer is exposed to light, albeit not quite completely, after which the photoresist layer is developed and post-baked to obtain tapered banks. A liquid material is applied to the region demarcated by these banks, and this material is solidified or cured to form a color element film.

However, with the color filter substrate pertaining to JP-A-2002-62422, in the formation of banks by photolithography, setting the exposure conditions is difficult because tapered banks have to be formed from a single photoresist layer. Also, because this color filter substrate continuously tapers in the width of the banks toward the base, there is only a small surface area at the junction between the banks and the base, so the banks tend to separate from the base during the formation of the bank by photolithography, which is a problem in that the yield is diminished in the manufacture of a color filter substrate.

### SUMMARY

It is an advantage of the invention to provide a method for manufacturing a color element film-equipped substrate, with which a high-quality color element film-equipped substrate can be obtained simply and at high production efficiency, as well as a color element film-equipped substrate, an electro-optical device, and an electronic device.

This advantage of the invention is realized as follows.

The method for manufacturing a color element film-equipped substrate of an aspect of the invention includes forming a bank, in which a first layer and a photo-curing second layer are laminated over a base, and parts of the first layer and the second layer are removed after exposing and developing the first layer and the second layer, with a remainder of the first layer and the second layer serving as a bank; applying a liquid material used for forming a color element film to a region demarcated by the bank; and forming a color element film by curing or solidifying the liquid material applied to the region. The first layer is soluble in a developing liquid during the developing, the second layer is soluble in the developing liquid but dissolves more slowly in the developing liquid than the first layer does, and the bank is formed with the width of the remainder of the second layer being greater than the width of the remainder of the first layer after the development.

Consequently, banks having a portion whose width steadily decreases toward the base can be easily formed without having to set the exposure conditions precisely in the bank formation step. More specifically, in the bank formation step, part of the second layer is put in a cured state by exposure, and part of the first layer and the uncured portion of the second layer are removed by developing. As a result, the portion in which the remainder of the second layer protrudes from the remainder of the first layer constitutes a protruding component of the color element film-equipped substrate of the inkjet (discussed below).

Also, in the application of liquid material, when the liquid material is applied to the regions demarcated by these banks, capillary action causes the liquid material to be drawn into every corner of the regions, even into the tiny gaps formed between the base and the portion where the remainder of the second layer protrudes beyond the remainder of the first layer (that is, the protruding component). As a result, a color element film-equipped substrate of higher quality can be obtained.

Also, since the width of the above-mentioned bank steadily decreases in stages toward the base, the surface area at the junction between the bank and the base can be comparatively increased. Accordingly, separation between the bank and the base can be prevented during developing in the bank formation step. As a result, a color element film-equipped substrate can be manufactured at higher production efficiency.

With the method for manufacturing a color element film-equipped substrate of this aspect of the invention, it is preferable if the second layer contains a photoresist material.

This allows the width of the remainder of the second layer to be made greater than the width of the remainder of the first layer both reliably and relatively easily.

With the method for manufacturing a color element film-equipped substrate of this aspect of the invention, it is preferable if, in forming the bank, prior to the exposure, a photo-curing third layer is formed on a side of the second layer opposite from the first layer.

As a result, exposure during the bank formation puts parts of the second layer and the third layer into a cured state, and developing removes part of the first layer and the uncured portions of the second layer and the third layer, allowing the width of the remainder of the second layer to be made greater than the width of the remainder of the first layer.

With the method for manufacturing a color element film-equipped substrate of this aspect of the invention, it is preferable if the second layer is a mixture of the material constituting the first layer and the material constituting the third layer.

This allows the first layer, second layer, and third layer to be easily formed on the base, merely by coating the base first with the material constituting the first layer and then with the material constituting the third layer during the bank formation.

With the method for manufacturing a color element film-equipped substrate of this aspect of the invention, it is preferable if, in the bank formation step, a width of a portion of the second layer that will be cured by the exposure during the forming of the bank is greater than a width of a portion of the third layer that will be cured by the exposure during the forming of the bank.

This allows the resulting bank to be narrower in its height direction with respect to the protruding component. When a liquid material is applied to the region demarcated by banks such as this, liquid material can be applied all the way up to the upper side of the protruding component, without the liquid material overflowing the banks and spilling out of the region. As a result, the film thickness can be made more uniform in the used portion of the color element film that is obtained, so a color element film-equipped substrate of higher quality can be manufactured.

With the method of manufacturing a color element film-equipped substrate, it is preferable if the third layer repels the liquid material.

This prevents the liquid material from overflowing the banks and spilling out of the region even if the surface of the liquid material applied to the region is higher than the banks during the liquid material application.

With the method for manufacturing a color element film-equipped substrate of this aspect of the invention, it is preferable if the first layer blocks light.

This allows the remainder of the first layer to function as a black matrix in the resulting color element film-equipped substrate.

The color element film-equipped substrate is manufactured by the method of the above-described aspect of the invention for manufacturing a color element film-equipped substrate.

Therefore, even if defects should occur in the edge portion of the color element film, this portion can be covered with a protruding component, which prevents problems such as color unevenness and decreased contrast.

The color element film-equipped substrate of another aspect of the invention has a base, a bank provided over the base, and a color element film formed in a region demarcated by the bank, wherein the bank has a protruding component that protrudes toward the inside of the region, at a point along the height of the bank.

Therefore, even if defects should occur in the edge portion of the color element film, this portion can be covered with a protruding component, which prevents problems such as color unevenness and decreased contrast.

With the color element film-equipped substrate of this aspect of the invention, it is preferable if the protruding component is formed over substantially the entire periphery of the region.

This more effectively prevents problems such as color unevenness and decreased contrast.

With the color element film-equipped substrate, it is preferable if the bank narrows in width above and below the protruding component.

This affords a more uniform film thickness in the used portion of the color element films, and more effectively prevents problems such as color unevenness and decreased contrast.

The electro-optical device of still another aspect of the invention is furnished with the color element film-equipped substrate of the aforementioned aspect of the invention.

Therefore, even if defects should occur in the edge portion of the color element film, this portion can be covered with a protruding component, which prevents problems such as color unevenness and decreased contrast.

The electronic device of still another aspect of the invention is furnished with the electro-optical device of the aforementioned aspect the invention.

Therefore, even if defects should occur in the edge portion of the color element film, this portion can be covered with a protruding component, which prevents problems such as color unevenness and decreased contrast.

### BRIEF DESCRIPTION OF THE DRAWINGS

FIG. 1 is an oblique view of an embodiment of the droplet discharge apparatus of an embodiment of the invention;

FIG. 2 consists of plan views of the head unit and substrate in the droplet discharge apparatus shown in FIG. 1;

FIG. 3 is a detail plan view of the substrate regions and part of the nozzle side (nozzle plate) of the droplet discharge head;

FIG. 4 illustrates a droplet discharge head in the droplet discharge apparatus shown in FIG. 1, with FIG. 4A being a cut-away oblique view, and FIG. 4B a cross section;

FIG. 5 is a block diagram of the droplet discharge apparatus shown in FIG. 1;

FIG. 6A is a schematic diagram of a head driver, and FIG. 6B is a timing chart illustrating the drive signals, selection signals, and discharge signals in the head driver;

FIG. 7 is a cross section of a method for manufacturing a color filter substrate;

FIG. 8 is a cross section of a method for manufacturing a color filter substrate;

FIG. 9 consists of cross sections of a method for manufacturing an organic electroluminescence display device;

FIG. 10 consists of cross sections of a method for manufacturing an organic electroluminescence display device;

FIG. 11 is an oblique view of the structure of a portable (or notebook) personal computer to which the electronic device of another embodiment of the invention has been applied;

FIG. 12 is an oblique view of the structure of a portable telephone (including a PHS) to which the electronic device of still another embodiment of the invention has been applied; and

FIG. 13 is an oblique view of the structure of a digital still camera to which the electronic device of still another embodiment of the invention has been applied.

### DESCRIPTION OF EXEMPLARY EMBODIMENTS

The method for manufacturing a color element film-equipped substrate, the color element film-equipped substrate, the image display device, and the electronic device of the embodiments of the invention will now be described in detail through the specific embodiments shown in the appended drawings.

In these embodiments, a color filter substrate 10, which is a constituent element of a liquid crystal display device, will be described as a typical example of the color element film-equipped substrate of an embodiment of the invention.

Overall Structure of Droplet Discharge Apparatus

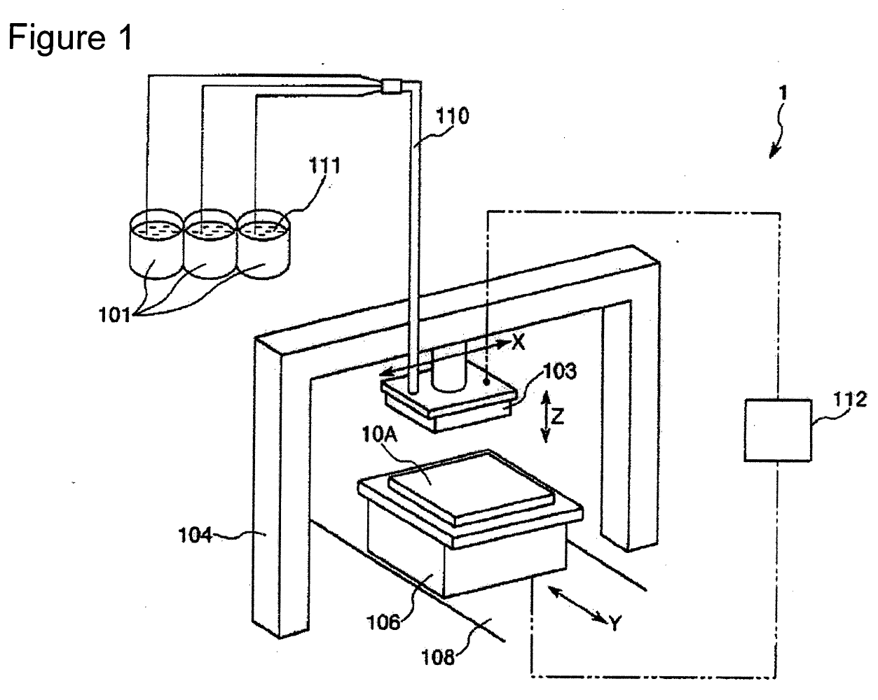

First, the droplet discharge apparatus used to manufacture the color element film-equipped substrate of the embodiment of the invention will be described through reference to FIGS. 1 to 6.

As shown in FIG. 1, a droplet discharge apparatus 1 includes a head unit 103 in which a plurality of droplet discharge heads 2 are mounted on a carriage 5, a carriage movement mechanism (movement means) 104 for moving the head unit 103 in one horizontal direction (hereinafter this direction will be referred to as the “X axis direction”), a stage 106 for holding a substrate 10A (discussed below), a stage movement mechanism (movement means) 108 for moving the stage 106 horizontally in a direction perpendicular to the X axis direction (hereinafter referred to as the “Y axis direction”), and a control means 112.

Three tanks 101 containing liquid materials 111 of three colors, namely, red (R), green (G), and blue (B), are provided near the droplet discharge apparatus 1. The tanks 101 are connected to the head unit 103 through a tube 110 that serves as a passage for delivering the liquid materials 111. The liquid material 111 contained in each tank 101 is pumped (supplied) to the corresponding droplet discharge head 2 of the head unit 103 by compressed air pressure, for instance.

The term “liquid material” as used in the embodiment of the invention includes materials for forming color element films in color element film-equipped substrates, and that have a viscosity that allow them to be discharged from nozzles 25 of the droplet discharge heads 2. The material here may be either water-based or oil-based. The material need only have a fluidity (viscosity) that allows discharge from the nozzles 25, and may have a solid substance dispersed within it as long as it is a fluid overall. Specifically, the liquid material may be one in which the constituent materials of the color element film are dissolved or dispersed, and may be either a solution or a dispersion (suspension or emulsion).

The liquid materials 111 in this embodiment are organic solvent inks produced by dissolving or dispersing in an organic solvent a pigment for forming a filter layer of a region of the color filter substrate 10. The liquid materials will be discussed in detail below.

In the following description, when the red, green, and blue liquid materials 111 need to be distinguished from one another, they will be numbered 111R, 111G, and 111B, but when they are referred to collectively and no distinction made, they will be referred to simply as the “liquid materials 111.”

The operation of the carriage movement mechanism 104 is controlled by the control means 112. The function of the carriage movement mechanism 104 in this embodiment is to operate the head unit 103 in the Z axis direction (vertically) to adjust the height of this unit. The carriage movement mechanism 104 also functions to rotate the head unit 103 around an axis parallel to the Z axis, which allows fine adjustment of the angle of the head unit 103 around the Z axis.

The stage 106 has a surface that is parallel to both the X axis direction and the Y axis direction. Also, the stage 106 is designed so that the substrate 10A used to manufacture the color filter substrate 10 can be fixed to or held on this surface.

The stage movement mechanism 108 moves the stage 106 in the Y axis direction, which is perpendicular to both the X axis direction and the Z axis direction, and this operation is controlled by the control means 112. Furthermore, the stage movement mechanism 108 in this embodiment also functions to rotate the stage 106 around an axis parallel to the Z axis, which allows the inclination of the substrate 10A placed on the stage 106 to be adjusted around the Z axis, so that it is straight.

As discussed above, the head unit 103 is moved in the X axis direction by the carriage movement mechanism 104. Meanwhile, the stage 106 is moved in the Y axis direction by the stage movement mechanism 108. In other words, the relative position of the head unit 103 in relation to the stage 106 is changed by the carriage movement mechanism 104 and the stage movement mechanism 108.

The structure and function of the control means 112 will be described in detail below.

Head Unit

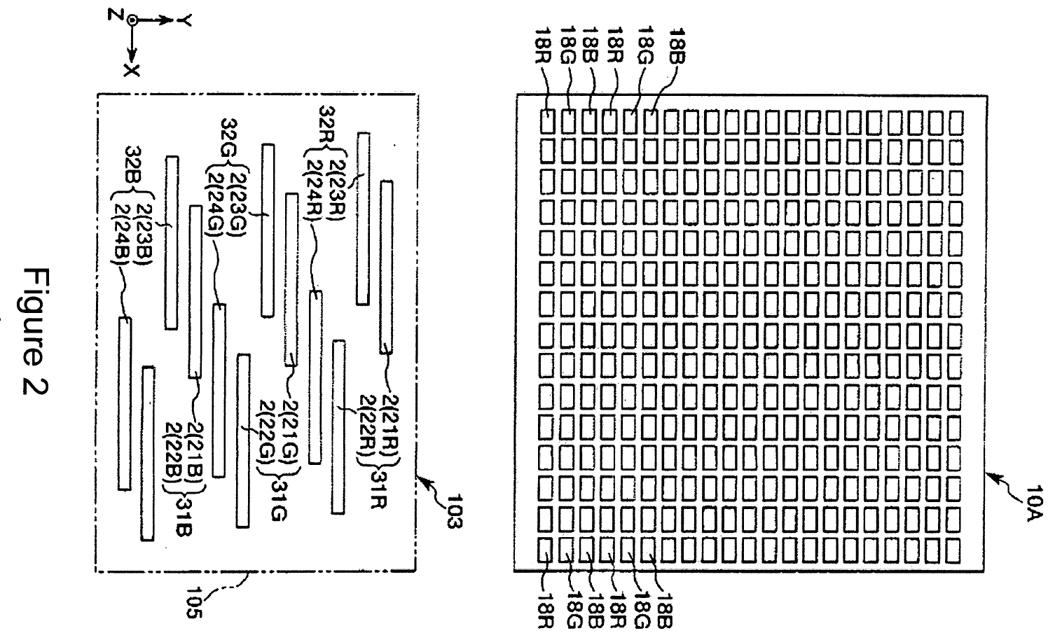

FIG. 2 is a plan view of the head unit 103 and the substrate 10A in the droplet discharge apparatus 1 shown in FIG. 1.

The head unit 103 shown in FIG. 2 includes a plurality of droplet discharge heads 2 mounted on a carriage 105. In FIG. 2, the carriage 105 is shown by an imaginary line (two-dot chain line). The solid lines indicating the droplet discharge heads 2 show the positions of the nozzle side (nozzle plate 128) of the droplet discharge heads 2.

The head unit 103 is provided with a total of 12 droplet discharge heads 2, consisting of four droplet discharge heads 2 for discharging the red liquid material 111R (a first head 21R, a second head 22R, a third head 23R, and a fourth head 24R), four droplet discharge heads 2 for discharging the green liquid material 111G (a first head 21G, a second head 22G, a third head 23G, and a fourth head 24G), and four droplet discharge heads 2 for discharging the blue liquid material 111B (a first head 21B, a second head 22B, a third head 23B, and a fourth head 24B).

In the following description, when these droplet discharge heads 2 are referred to collectively, they will be called simply the droplet discharge heads 2, but when they need to be distinguished from one another, they will be called the first head 21R, second head 22R, and so forth.

The substrate 10A shown in FIG. 2 is used to manufacture a color filter substrate 10 with a stripe arrangement. This substrate 10A is provided with numerous red regions 18R (discharge regions), green regions 18G (discharge regions), and blue regions 18B (discharge regions). The droplet discharge apparatus 1 applies the red liquid material 111R to the red regions 18R, applies the green liquid material 111G to the green regions 18G, and applies the blue liquid material 111B to the blue regions 18B.

The regions 18R, 18G, and 18B are substantially rectangular. The substrate 10A is supported on the stage 106 in an orientation such that the long axis direction of the regions 18R, 18G, and 18B is parallel to the X axis direction, and the short axis direction is parallel to the Y axis direction. The regions are arranged on the substrate 10A in a three-color repeating pattern of 18R, 18G, and 18B in the Y axis direction, and regions of the same colors are arranged in the X axis direction. One set of regions 18R, 18G, and 18B lined up in the Y axis direction corresponds to one region of the manufactured color filter substrate 10.

Droplet Discharge Head

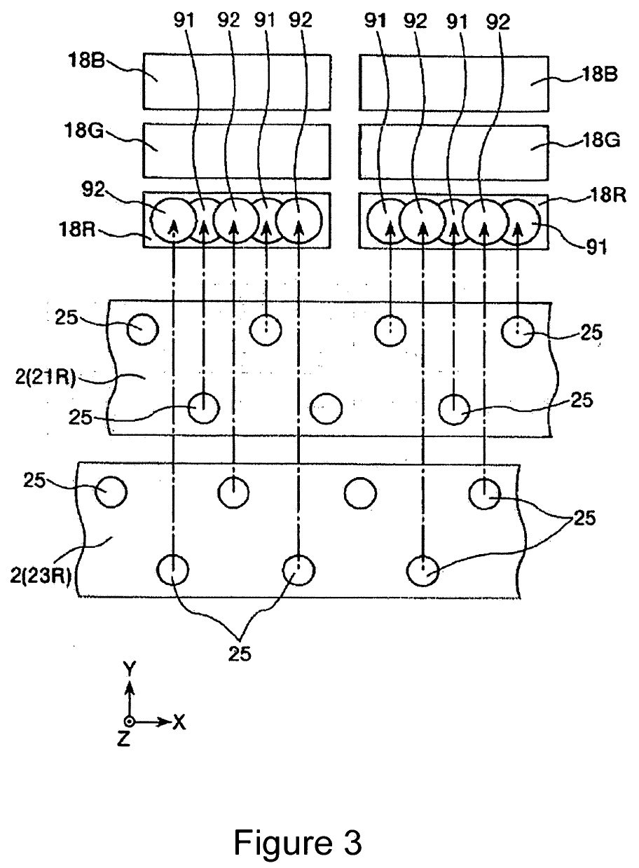

FIG. 3 is an enlarged plan view of part of the nozzle side (nozzle plate 128) of the droplet discharge heads 2 and the regions of the substrate 10A. The nozzle side of the droplet discharge heads 2 is provided in a direction that is across from the substrate 10A, that is, facing vertically downward, but in FIG. 3 the nozzle side of the droplet discharge heads 2 is indicated with solid lines to make it easier to see.

Numerous nozzles (nozzle holes) 25 are formed in the nozzle side of the droplet discharge heads 2, spaced equidistantly in a straight line in the X axis direction. In this embodiment, two rows or nozzles are formed, staggered at half pitch, in one droplet discharge head 2, but the number of nozzle rows had by each droplet discharge head 2 may be one or may be three or more. There are no particular restrictions on the number of nozzles 25 formed in one droplet discharge head 2, but the number is usually anywhere from a few dozen to a few hundred.

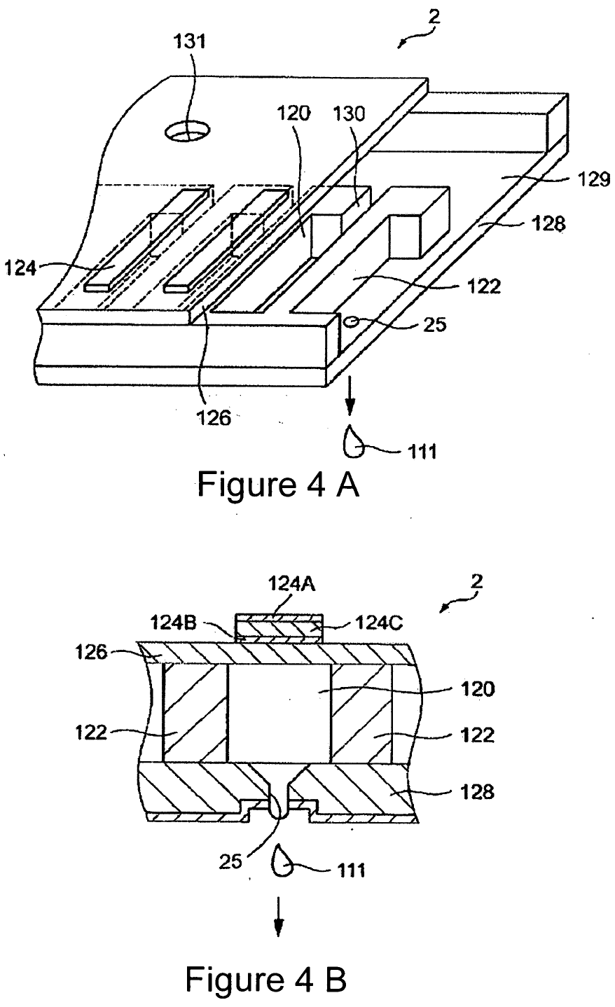

As shown in FIGS. 4A and 4B, the droplet discharge heads 2 are inkjet heads. More specifically, each droplet discharge head 2 includes a diaphragm 126 and the nozzle plate 128. A liquid reservoir 129 that is kept filled with liquid material 111 supplied from a tank 101 through a hole 131 is located between the diaphragm 126 and the nozzle plate 128.

A plurality of barriers 122 are located between the diaphragm 126 and the nozzle plate 128. The portion surrounded by the diaphragm 126, the nozzle plate 128, and a pair of barriers 122 is a cavity 120. Since the cavities 120 are provided corresponding to the nozzles 25, the number of cavities 120 is the same as the number of nozzles 25. The liquid material 111 is supplied from the liquid reservoir 129, through a supply hole 130 located between two barriers 122, to the cavity 120.

A transducer 124 that serves as a drive element for varying the pressure of the liquid material 111 filling the cavity 120 is located corresponding to each of the cavities 120. Each transducer 124 includes a piezo element 124C and a pair of electrodes 124A and 124B flanking the piezo element 124C. Drive voltage is applied between the electrodes 124A and 124B, which causes the liquid material 111 to be discharged from the corresponding nozzle 25. The shape of the nozzles 25 is adjusted so that the liquid material 111 will be discharged in the Z axis direction from the nozzles 25.

The control means 112 (FIG. 1) may be constituted so that mutually independent signals are sent to the plurality of transducers 124. In other words, the volume of the liquid material 111 discharged from the nozzles 25 may be controlled for every nozzle 25 according to the signals from the control means 112.

The droplet discharge head 2 is not limited to one in which the drive element is a voltage actuator as shown in the drawings, and may instead make use of an electrostatic actuator, or may discharge droplets by using an electro-thermal conversion element and utilizing the thermal expansion of the liquid material 111.

Control Means

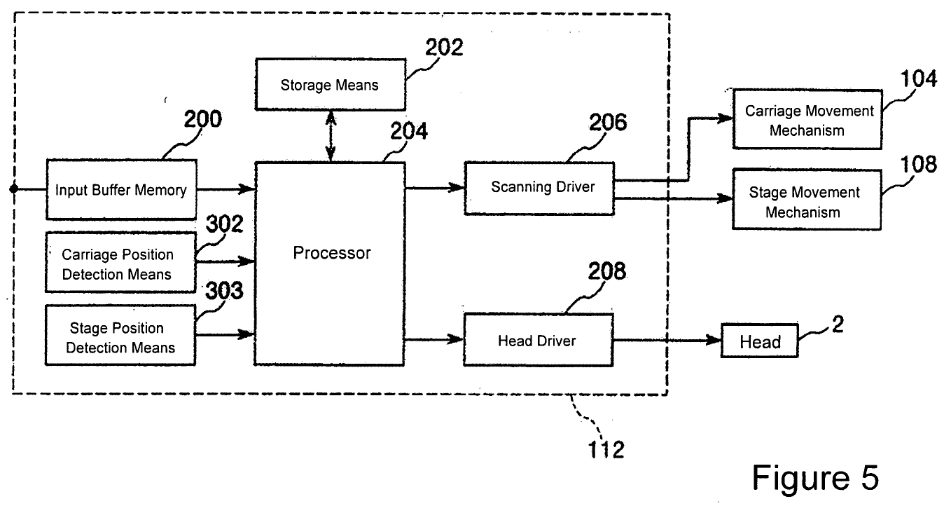

The constitution of the control means 112 will now be described. As shown in FIG. 5, the control means 112 includes an input buffer memory 200, a storage means 202, a processor 204, a scanning driver 206, a head driver 208, a carriage position detection means 302, and a stage position detection means 303.

The input buffer memory 200 and the processor 204 are connected so that they can communicate with each other. The processor 204 and the storage means 202 are also connected so that they can communicate with each other. The processor 204 and the scanning driver 206 are also connected so that they can communicate with each other. The processor 204 and the head driver 208 are also connected so that they can communicate with each other. The scanning driver 206 is also connected so that it can communicate with the carriage movement mechanism 104 and the stage movement mechanism 108. Similarly, the head driver 208 is connected so that it can communicate with each of the plurality of droplet discharge heads 2.

The input buffer memory 200 receives data relating to the position where the droplets of liquid material 111 are discharged, that is, drawing pattern data, from an external information processing device. The input buffer memory 200 supplies this drawing pattern data to the processor 204, and the processor 204 stores the drawing pattern data in the storage means 202. The storage means 202 consists of a RAM, a magnetic recording medium, an opto-magnetic recording medium, or the like.

The carriage position detection means 302 detects the position of the carriage 105, that is, its position in the X axis direction of the head unit 103 (movement distance), and the processor 204 inputs this detection signal.

The stage position detection means 303 detects the position of the stage 106, that is, its position in the Y axis direction of the substrate 10A (movement distance), and the processor 204 inputs this detection signal.

The carriage position detection means 302 and the stage position detection means 303 consist of a linear encoder, a laser measuring device, or the like, for example.

The processor 204 controls (closed loop control) the operation of the carriage movement mechanism 104 and the stage movement mechanism 108 through the scanning driver 206 on the basis of the detection signals received from the carriage position detection means 302 and the stage position detection means 303, and controls the position of the head unit 103 and the position of the substrate 10A.

Further, the processor 204 controls the movement speed of the stage 106, that is, the substrate 10A, by controlling the operation of the stage movement mechanism 108.

Also, the processor 204 applies selection signals SC, which specify whether the nozzles 25 are on or off at each discharge timing, to the head driver 208 on the basis of the above-mentioned drawing pattern data. The head driver 208 applies the discharge signals ES required for the discharge of the liquid material 111 to the droplet discharge heads 2 on the basis of the selection signals SC. As a result, the liquid material 111 is discharged as droplets from the nozzles 25 corresponding to the droplet discharge heads 2.

The control means 112 may be a computer that includes a CPU, ROM, and RAM. In this case, the above-mentioned functions of the control means 112 will be constituted by software programs executed by the computer. Naturally, the control means 112 may also include a dedicated circuit (hardware).

The structure and function of the head driver 208 in the control means 112 will now be described.

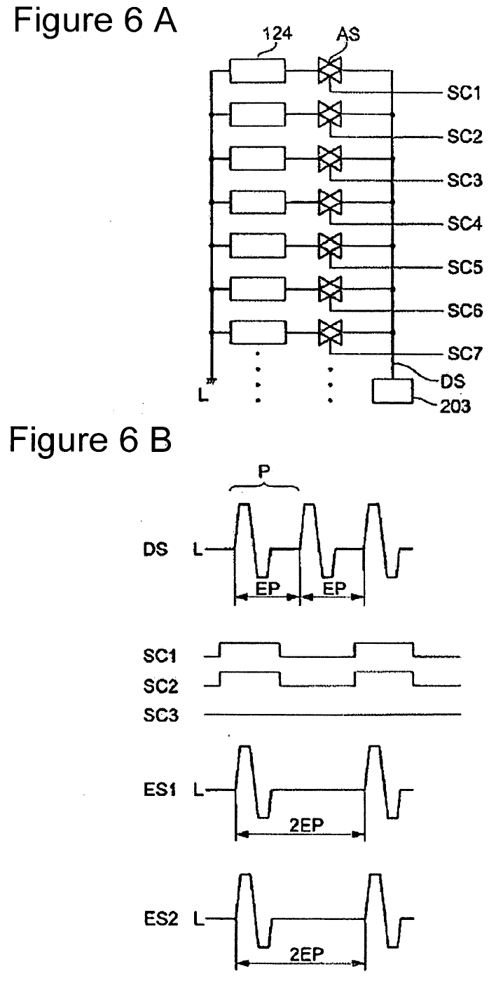

As shown in FIG. 6A, the head driver 208 has one drive signal generator 203 and a plurality of analog switches AS. As shown in FIG. 6B, the drive signal generator 203 generates a drive signal DS. The potential of the drive signal DS varies over time with respect to a reference potential L. More specifically, the drive signal DS includes a plurality of discharge waveforms P that are repeated in a discharge period EP. The discharge waveform P here corresponds to a drive voltage waveform that is to be applied to the pair of electrodes of the corresponding transducer 124 in order to discharge a single droplet from a nozzle 25.

The drive signals DS are supplied to the input terminals of the analog switches AS. The analog switches AS are provided corresponding to the nozzles 25. That is, the number of analog switches AS is the same as the number of nozzles 25.

The processor 204 sends selection signals SC, which express whether the nozzles 25 are on or off, to the analog switches AS. The selection signals SC here can be at either a high level or a low level, independently for each of the analog switches AS. Meanwhile, the analog switches AS supply discharge signals ES to the electrodes 124A of the transducers 124 according to the drive signals DS and the selection signals SC. More specifically, when a selection signal SC is at a high level, the analog switch AS propagates a drive signal DS as a discharge signal ES to the electrode 124A. When a selection signal SC is at a low level, however, the potential of the discharge signal ES discharged by the analog switch AS is the reference potential L. When a drive signal DS is applied to the electrode 124A of the transducer 124, the liquid material 111 is discharged from the nozzle 25 corresponding to that transducer 124. The reference potential L is applied to the electrode 124B of each of the transducers 124.

In the example shown in FIG. 6B, the high level period and the low level period are set in each of two selection signals SC so that the discharge waveform P will appear at a period 2EP that is twice the discharge period EP in each of two discharge signals ES. As a result, the liquid material 111 is discharged at the period 2EP from each of two corresponding nozzles 25. Also, a common drive signal DS from the drive signal generator 203 is applied to each of the transducers 124 corresponding to these two nozzles 25. Accordingly, the liquid material 111 is discharged at substantially the same timing from the two nozzles 25.

With this droplet discharge apparatus 1, the operation of the stage movement mechanism 108 moves the substrate 10A, which is held on the stage 106, in the Y axis direction, and causes droplets of the liquid material 111 to be discharged from the nozzles 25 of the droplet discharge heads 2 of the head unit 103 while the substrate 10A passes under the head unit 103, so that the discharged droplets are applied to (made to land in) the regions 18R, 18G, and 18B on the substrate 10A. This operation will hereinafter be referred to as the “main scanning of the head unit 103 and the substrate 10A.”

If the width of the substrate 10A in the X axis direction is less than the length in the X axis direction in which the liquid material 111 can be discharged with respect to the substrate 10A for the head unit 103 as a whole (the total discharge width W, discussed below), then the liquid material 111 can be applied to the entire substrate 10A by just one main scan of the head unit 103 and the substrate 10A.

In contrast, if the width of the substrate 10A in the X axis direction is greater than the total discharge width W of the head unit 103, then the liquid material 111 can be applied to the entire substrate 10A by alternately repeating the main scanning of the head unit 103 and the substrate 10A with the movement of the head unit 103 in the X axis direction by operation of the carriage movement mechanism 104 (this is called “sub-scanning”).

Method for Manufacturing a Color Element Film-Equipped Substrate of the Embodiments of the Invention, and Color Element Film-Equipped Substrate of the Embodiments of the Invention

Next, the method for manufacturing the color filter substrate 10 using the droplet discharge apparatus 1 discussed above will be described in detail as an example of the method of the invention for manufacturing a color element film-equipped substrate.

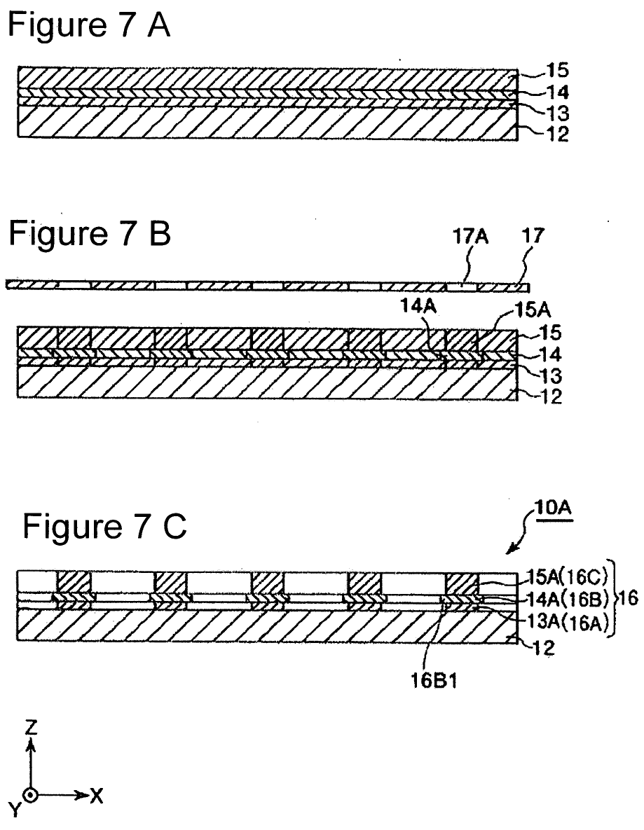

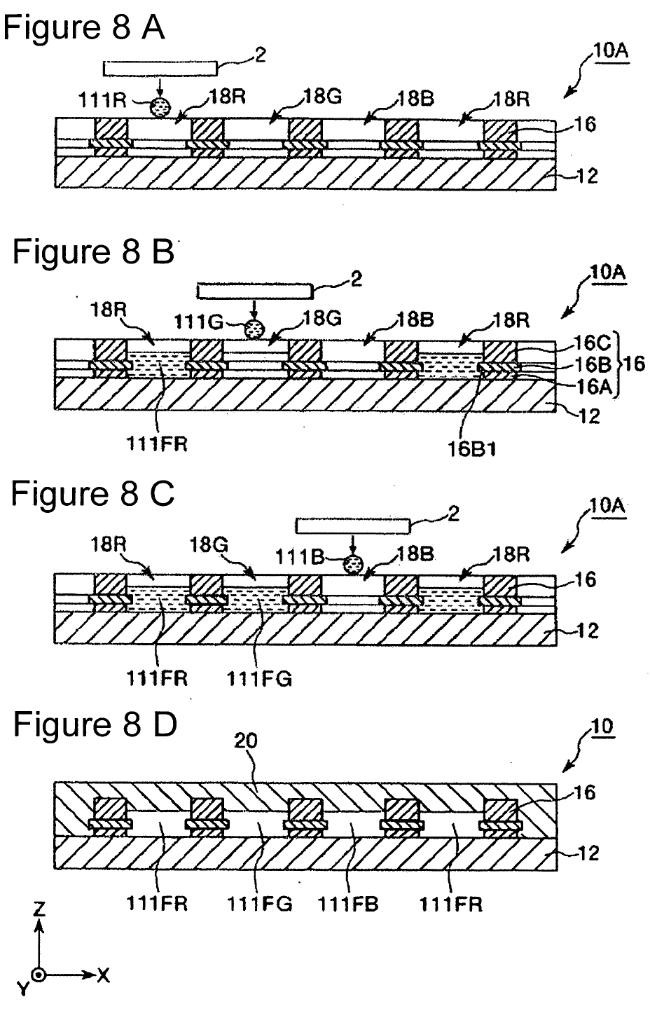

FIGS. 7 and 8 are cross sections illustrating the method for manufacturing the color filter substrate 10.

The method for manufacturing the color filter substrate 10 includes a bank formation step of forming a bank that demarcates the regions 18 (that is, the production of the substrate 10A), a liquid material application step of applying liquid material 111 for forming a color element film in the regions 18, and a color element film formation step of forming a filter layer that is a color element film. Each of these steps will be discussed below in order.

Bank Formation Step

In manufacturing the color filter substrate 10, first the substrate 10A is produced, that is, a bank 16 is formed over a base 12.

As shown in FIG. 7C, the substrate 10A includes an optically transmissive base 12, and a bank 16 formed over the base 12.

The base 12 is a substrate that is optically transmissive to visible light, such as a glass substrate.

The bank 16 is produced by laminating a first portion 16A over the base 12, a second portion 16B over this, and a third portion 16C over this.

The second portion 16B is wider than the first portion 16A and the third portion 16C. Because of this, the portion where the second portion 16B protrudes beyond the first portion 16A and the third portion 16C constitutes protruding components 16B1 (ribs). Specifically, the banks 16 have protruding components 16B1 that protrude toward the inside of the regions 18.

Because the third portion 16C is narrower than the second portion 16B, this affords greater volume in the regions bounded by the banks 16.

Each of the banks 16 constituted as above is positioned so as to define a plurality of matrix-shaped optically transmissive portions, namely, the plurality of matrix-shaped regions 18R, 18G, and 18B, on the base 12. Specifically, the regions 18R, 18G, and 18B are demarcated by the base 12 and the banks 16.

The regions 18R are regions where a filter layer 111FR is to be formed, which is a color element film that transmits only light whose wavelength is in the red band, the regions 18G are regions where a filter layer 111FG is to be formed, which is a color element film that transmits only light whose wavelength is in the green band, and the regions 18B are regions where a filter layer 111FB is to be formed, which is a color element film that transmits only light whose wavelength is in the blue band.

The following procedure is followed to produce this substrate 10A, that is, to form the banks 16 on the base 12.

First, as shown in FIG. 7A, a first layer 13 is formed over the base 12, a second layer 14 over this, and a third layer 15 over this, all by sputtering or vapor deposition.

After this, as shown in FIG. 7B, portions 14A and 15A of the second layer 14 and the third layer 15 are put in a cured state by exposure using a mask 17 formed in a matrix pattern by photolithography, and as shown in FIG. 7C, the uncured portions of the second layer 14 and the third layer 15 and part of the first layer 13 are removed by developing to obtain banks 16. Here, because the second layer 14 dissolves in the developing solution used for developing more slowly than the first layer 13, the width of the remainder of the second layer 14 is greater than the width of the remainder of the first layer 13. Also, in this embodiment, as a result of developing, the remainder 13A of the first layer 13 becomes the first portion 16A, substantially all of the portion 14A of the second layer 14 becomes the remainder of the second layer 14 (that is, the second portion 16B), and substantially all of the portion 15A of the third layer 15 becomes the remainder of the third layer 15 (that is, the third portion 16C).

In this bank formation step, the first layer 13 is soluble in the developing solution used for developing, and the second layer 14 is soluble in the developing solution but dissolves in the developing solution more slowly than the first layer 13. Therefore, the width of the remainder (portion 14A) of the second layer 14 is greater than the width of the remainder 13A of the first layer 13.

Consequently, banks 16 having portions whose width steadily decreases toward the base 12 can be easily formed even though the exposure conditions are not strictly set in the bank formation step. More specifically, in the bank formation step, exposure puts the portion 14A of the second layer 14 into a cured state, and developing removes the uncured portion of the second layer 14 and part of the first layer 13. As a result, the portion where the remainder of the second layer 14 protrudes beyond the remainder of the first layer 13 constitutes the protruding component 16B1.

Because the width of the banks 16 discussed above steadily decreases in stages toward the base 12, the surface area at the junction between the banks and the base can be comparatively increased. Accordingly, separation between the banks 16 and the base 12 can be prevented during developing in the bank formation step. As a result, the color filter substrate 10 can be manufactured at higher production efficiency.

With this bank formation step, the second layer 14 and the third layer 15 may be made of a photo-curing material, but in this embodiment they contain a photoresist material. This allows the width of the remainder of the second layer 14 (the portion 14A of the second layer 14) to be made greater than the width of the remainder 13A of the first layer 13 both reliably and relatively easily.

With this embodiment, a negative photoresist material is used as the material constituting the second layer 14 and the third layer 15. Therefore, the mask 17 used in the exposure treatment has an opening 17A corresponding to the plan view shape of the banks 16. However, a positive photoresist material can also be used as the material constituting the second layer 14 and the third layer 15. In this case, a mask whose pattern is inverted from the pattern of the mask 17 is used instead of the mask 17.

Also, in this embodiment, the third layer 15 is made of a photoresist material. Specifically, in the bank formation step, prior to the exposure, a photo-curing third layer is formed on the opposite side of the second layer 14 from the first layer 13. Therefore, exposure during the bank formation step puts the portions 14A and 15A of the second layer 14 and third layer 15 into a cured state, and developing removes part of the first layer 13 and the uncured portions of the second layer 14 and third layer 15, allowing the width of the remainder of the second layer 14 (the portion 14A of the second layer 14) to be made greater than the width of the remainder 13A of the first layer 13.

Also, it is preferable if the second layer 14 is a mixture of the material constituting the first layer 13 and the material constituting the third layer 15. This allows the first layer 13, second layer 14, and third layer 15 to be easily formed on the base 12, merely by coating the base 12 first with the material constituting the first layer 13 and then with the material constituting the third layer 15 in the bank formation step.

Also, in the bank formation step, the exposure makes the width of the portion of the second layer 14 that will be in a cured state (that is, the portion 14A of the second layer 14) greater than the width of the portion of the third layer 15 that will be in a cured state. This allows the resulting bank 16 to be narrower in its height direction with respect to the portion where the second layer 14 protrudes beyond the first layer 13 (that is, the protruding component 16B1). When the liquid material 111 is applied to the region 18 demarcated by banks such as this, liquid material can be applied all the way up to the upper side of the protruding component 16B1, without the liquid 111 material overflowing the banks 16 and spilling out of the region. As a result, the film thickness can be made more uniform in the used portion of the color element film 111F that is obtained, so a color filter substrate 10 of higher quality can be manufactured.

It is also preferable if the third layer 15 repels the liquid material 111. This prevents the liquid material 111 from overflowing the banks and spilling out of the region 18 even if the surface of the liquid material 111 applied to the region 18 is higher than the banks in the liquid material application step.

Also, it is preferable if the first layer 13 blocks light. This allows the remainder of the first layer to function as a black matrix in the resulting color element film-equipped substrate. In this case, for example, the first layer 13 can contain a material such as carbon black.

The above steps yield the substrate 10A.

Liquid Material Application Step

The substrate 10A on which the regions 18R, 18G, and 18B have been formed as above is conveyed over the stage 106 of the droplet discharge apparatus 1 and supported on the stage 106. The droplet discharge apparatus 1 operates the stage movement mechanism 108 to move the substrate 10A in the Y axis direction so that it passes under the head unit 103 while droplets of the liquid material 111 from the droplet discharge heads 2 are discharged, applying the material to the regions 18R, 18G, and 18B.

More specifically, as shown in FIGS. 7A to 7C, the red liquid material (color filter material) 111R is discharged into the region 18R, the green liquid material (color filter material) 111G is discharged into the region 18G, and the blue liquid material (color filter material) 111B is discharged into the region 18B. Consequently, as shown in FIG. 8D, the liquid material 111R is applied to the region 18R, the liquid material 111G to the region 18G, and the liquid material 111B to the region 18B. Since the liquid material 111 is applied to the regions 18 here in the form of droplets from the nozzles 25, the desired amount of liquid material 111 can be applied more accurately to the regions 18 in the liquid material application step.

As discussed above, the liquid materials 111R, 111G, and 111B are organic solvent inks produced by dissolving or dispersing pigments, which are the constituent materials of the filter layers 111FR, 111FG, and 111FB of the regions of the color filter substrate 10, in an organic solvent.

In this liquid material application step, when the liquid material 111 is applied to the regions 18 demarcated by the above-mentioned banks 16, capillary action around the edges of the regions 18 draws the liquid material 111 into the tiny gaps formed between the base 12 and the portion where the remainder of the second layer 14 protrudes beyond the remainder of the first layer (that is, the protruding component 16B1), so that the material spreads out into every corner of the regions. As a result, a color filter substrate 10 of higher quality can be obtained.

Color Element Film Formation Step

Next, once the liquid materials 111R, 111G, and 111B have been applied to the regions 18R, 18G, and 18B, the color filter substrate 10 is conveyed to a drying apparatus (not shown), and the liquid materials 111R, 111G, and 111B inside the regions 18R, 18G, and 18B are dried. This yields the filter layers 111FR, 111FG, 111FB in the regions 18R, 18G, and 18B, as shown in FIG. 8D. The final filter layers 111FR, 111FG, 111FB may also be formed by alternating between application of the liquid materials 111R, 111G, and 111B with the droplet discharge apparatus 1 and drying with the drying apparatus, and repeatedly laminating layers.

After this, the substrate 10A is conveyed into an oven (not shown), and the filter layers 111FR, 111FG, 111FB are once again heated (post-baked) in this oven.

Next, the substrate 10A is conveyed to a protective film formation apparatus (not shown), and a protective film (overcoat) 20 that covers the filter layers 111FR, 111FG, and 111FB and the banks 16 is formed by this protective film formation apparatus as shown in FIG. 8D.

After the protective film 20 that covers the filter layers 111FR, 111FG, and 111FB and the banks 16 has been formed, the protective film 20 is completely dried with a drying apparatus. The protective film 20 is then further heated with a curing apparatus (not shown), which results in the substrate 10A becoming the color filter substrate 10.

With the color filter substrate 10, which is a color element film-equipped substrate obtained as above, even if defects should occur in the edge portion of the filter layers 111F (color element films), because this portion is covered by the protruding component 16B1, the problems color unevenness and decreased contrast can be prevented.

The protruding component 16B1 is preferably formed over substantially the entire periphery of the region. This more effectively prevents the problems of color unevenness and decreased contrast.

Also, the bank 16 narrows in width in the height direction of the bank 16 with respect to the protruding component 16B1. This affords a more uniform film thickness in the used portion of the filter layers 111F, and more effectively prevents the problems of color unevenness and decreased contrast.

The present invention as described above is not limited to the manufacture of the color filter substrate 10, and can also be applied, for example, to the manufacture of other types of image display device, such as an electroluminescence display device.

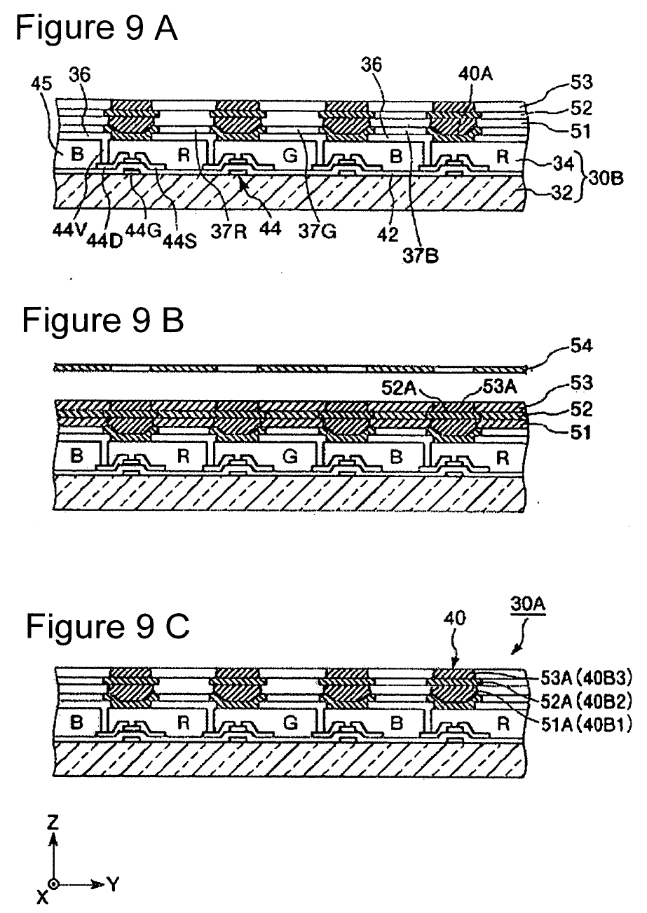

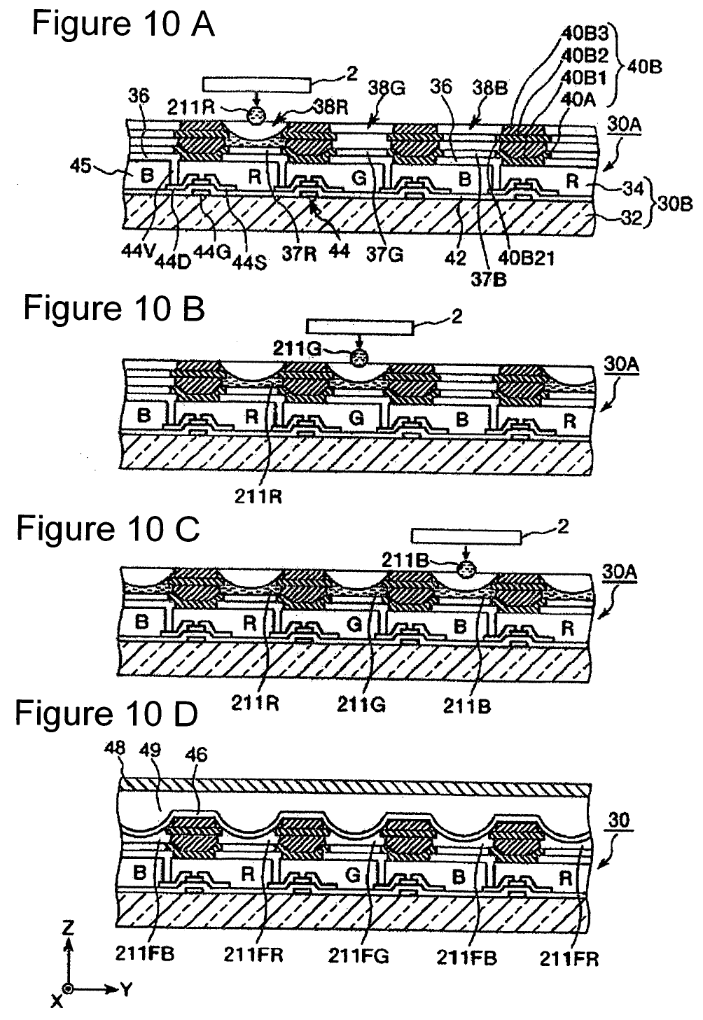

FIGS. 9 and 10 are cross sections illustrating a method for manufacturing an organic electroluminescence display device 30. The following description is of the manufacture of the organic electroluminescence display device 30 with an embodiment of the invention, but the description will focus on the differences from when the above-mentioned color filter substrate 10 is manufactured, and parts that are the same will not be described again.

The substrate 30A shown in FIGS. 9 and 10 is a substrate for manufacturing the organic electroluminescence display device 30.

Bank Formation Step

In the manufacture of the organic electroluminescence display device 30, first the substrate 30A is produced, that is, a bank 40 is formed over a base 30B.

A plurality of regions (discharge regions) 38R, 38G, and 38B arranged in a matrix are formed on this substrate 30A.

More specifically, the substrate 30A includes the base 30B and banks 40B. The base 30B includes a supporting substrate 32, a circuit element layer 34 formed over the supporting substrate 32, a plurality of region electrodes 36 formed over the circuit element layer 34, and an inorganic layer 40A formed between the plurality of region electrodes 36.

The supporting substrate 32 is a substrate that is optically transmissive to visible light, such as a glass substrate. Each of the plurality of region electrodes 36 is an electrode that is optically transmissive to visible light, such as an ITO (Indium-Tin Oxide) electrode. The region electrodes 36 are arranged in a matrix over the circuit element layer 34, each defining a region. The banks 40B have a lattice shape, and surround the region electrodes 36. The banks 40B here are organic banks formed over the inorganic layer 40A.

The banks 40B consist of a first portion 40B1 laminated over the base 30B, a second portion 40B2 over this, and a third portion 40B3 over this.

The second portion 40B2 is wider than the first portion 40B1 and the third portion 40B3. Because of this, the portion where the second portion 40B2 protrudes beyond the first portion 40B1 and the third portion 40B3 constitutes protruding components 40B21 (ribs). Specifically, the banks 40B have protruding components 40B21 that protrude toward the inside of the regions 38.

Because the third portion 40B3 is narrower than the second portion 40B2, this affords greater volume in the regions bounded by the banks 40B.

The circuit element layer 34 is a layer including a plurality of scanning electrodes extending in a specific direction over the supporting substrate 32, an insulating film 42 formed so as to cover the plurality of scanning electrodes, a plurality of signal electrodes located over the insulating film 42 and extending perpendicular to the direction in which the plurality of scanning electrodes extend, a plurality of switching elements 44 positioned at the intersections between the scanning electrodes and the signal electrodes, and an interlayer insulating film 45 made of polyimide or the like and formed so as to cover the plurality of switching elements 44. Each of the switching elements 44 has a gate electrode 44G and a source electrode 44S which are electrically connected to the corresponding scanning electrode and the corresponding signal electrode. The plurality of region electrodes 36 are positioned over the interlayer insulating film 45. Through-holes 44V are provided to the interlayer insulating film 45 at locations corresponding to the drain electrodes 44D of the switching elements 44, and an electrical connection between the switching elements 44 and the corresponding region electrodes 36 is formed through these through-holes 44V. The switching elements 44 are positioned at positions corresponding to the banks 40B. In other words, when viewed from above in FIG. 10, each of the switching elements 44 is positioned so as to be covered by a bank 40B.

Recesses defined by the banks 40B and the region electrodes 36 of the substrate 30A correspond to regions 38R, regions 38G, and regions 38B. The regions 38R are regions where a light emitting layer 221FR that emits light in the red wavelength band is to be formed, the regions 38G are regions where a light emitting layer 221FG that emits light in the green wavelength band is to be formed, and the regions 38B are regions where a light emitting layer 221FB that emits light in the blue wavelength band is to be formed.

This substrate 30A can be manufactured by forming the banks 40 by the same manufacturing steps as those used for the substrate 10A of the color filter substrate 10 above, and by using known film formation technology and patterning technology.

Specifically, first, as shown in FIG. 9A, the circuit element layer 34, the region electrodes 36, and the inorganic layer 40A are formed over the supporting substrate 32, a first layer 51 is formed over the resulting base 30B, a second layer 52 is formed over this, and a third layer 53 is formed over this, all by sputtering or vapor deposition.

After this, as shown in FIG. 9B, portions 52A and 53A of the second layer 52 and the third layer 53 are put in a cured state by exposure using a mask 54 formed in a matrix pattern by photolithography, and as shown in FIG. 9C, the uncured portions of the second layer 52 and the third layer 53 and part of the first layer 51 are removed by developing to obtain banks 16. Here, because the second layer 52 dissolves in the developing solution used for developing more slowly than the first layer 51, the width of the remainder of the second layer 52 is greater than the width of the remainder of the first layer 51. Also, in this embodiment, as a result of developing, the remainder 51A of the first layer 51 becomes the first portion 40B1, substantially all of the portion 52A of the second layer 52 becomes the remainder of the second layer 52 (that is, the second portion 40B2), and substantially all of the portion 53A of the third layer 53 becomes the remainder of the third layer 53 (that is, the third portion 40B3).

In this bank formation step, the first layer 51 is soluble in the developing solution used for developing, and the second layer 52 is soluble in the developing solution but dissolves in the developing solution more slowly than the first layer 51. Therefore, the width of the remainder of the second layer 52 is greater than the width of the remainder of the first layer 51.

Consequently, banks 40 having portions whose width steadily decreases toward the base 30B can be easily formed even though the exposure conditions are not strictly set in the bank formation step. More specifically, in the bank formation step, exposure puts the portion 52A of the second layer 52 into a cured state, and developing removes the uncured portion of the second layer 52 and part of the first layer 51. As a result, the portion where the remainder of the second layer 52 protrudes beyond the remainder 51A of the first layer 51 constitutes the protruding component 40B21.

Because the width of the banks 40B discussed above steadily decreases in stages toward the base 30B, the surface area at the junction between the banks 40B and the base 30B can be comparatively increased. Accordingly, separation between the banks 40B and the base 30B can be prevented during developing in the bank formation step. As a result, the organic electroluminescence display device 30 can be manufactured at higher production efficiency.

Corresponding hole transport layers 37R, 37G, and 37B may further be formed over the region electrodes 36. If the hole transport layers 37R, 37G, and 37B are positioned between the region electrodes 36 and the light emitting layers 211FR, 211FG, and 211FB (discussed below), the light emitting efficiency of the electroluminescence display device will be higher.

Liquid Material Application Step

Liquid materials 211R, 211G, and 211B are applied as shown in FIGS. 10A-10D to the regions 38R, 38G, and 38B, respectively, of the substrate 30A on which the regions 38R, 38G, and 38B were formed as above, using the droplet discharge apparatus 1 of the embodiment of the invention in the same manner as with the above-mentioned color filter substrate 10 as shown in FIGS. 8A-8D.

The liquid material 211R contains a red organic light emitting material, the liquid material 211G contains a green organic light emitting material, and the liquid material 211B contains a blue organic light emitting material.

As mentioned above, the liquid materials 211R, 211G, and 211B are produced by dissolving or dispersing light emitting materials, which are the constituent materials of the light emitting layers 211FR, 211FG, and 211FB of the regions of the organic electroluminescence display device 30, in an organic solvent.

In this liquid material application step, when the liquid material 211 is applied to the regions 38 demarcated by the above-mentioned banks 40, capillary action around the edges of the regions 38 draws the liquid material 211 into the tiny gaps formed between the region electrodes 36 of the base 30B and the portion where the remainder of the second layer 52 protrudes beyond the remainder of the first layer 51 (that is, the protruding component 40B21), so that the material spreads out into every corner of the regions 38. As a result, a organic electroluminescence display device 30 of higher quality can be obtained.

Color Element Film Formation Step

After this, the substrate 30A is moved to a drying apparatus and the liquid materials 211R, 211G, and 211B applied to the regions 38R, 38G, and 38B are dried. This yields the light emitting layers 211FR, 211FG, and 211FB in the regions 38R, 38G, and 38B, as shown in FIG. 10D.

Next, a counter electrode 46 is provided so as to cover the light emitting layers 211FR, 211FG, and 211FB and the banks 40. The counter electrode 46 functions as a cathode.

After this, a sealing substrate 48 and the substrate 30A are bonded together around their periphery to obtain the organic electroluminescence display device 30 shown in FIG. 10D. An inert gas 49 is charged in between the sealing substrate 48 and the substrate 30A.

With the organic electroluminescence display device 30, the light emitted from the light emitting layers 211FR, 211FG, and 211FB is emitted through the region electrodes 36, the circuit element layer 34, and the supporting substrate 32. An electroluminescence display device that thus emits light through a circuit element layer 34 is called a bottom emission display device.

The above descriptions were of applying an embodiment of the invention to the manufacture of a liquid crystal display device (color filter substrate) and to the manufacture of an electroluminescence display device, but the invention is not limited to these, and can also be applied, for example, to the manufacture of the back substrate of a plasma display device, or the manufacture of an image display device equipped with electron emitting elements (called an SED (Surface-conduction Electron emitter Display) or FED (Field Emission Display)).

### Embodiment of the Electronic Device

An image display device 100, such as a liquid crystal display device equipped with the color filter substrate 10 manufactured by the above method, or an electroluminescence display device manufactured by the above method, can be used for the display components of various kinds of electronic device.

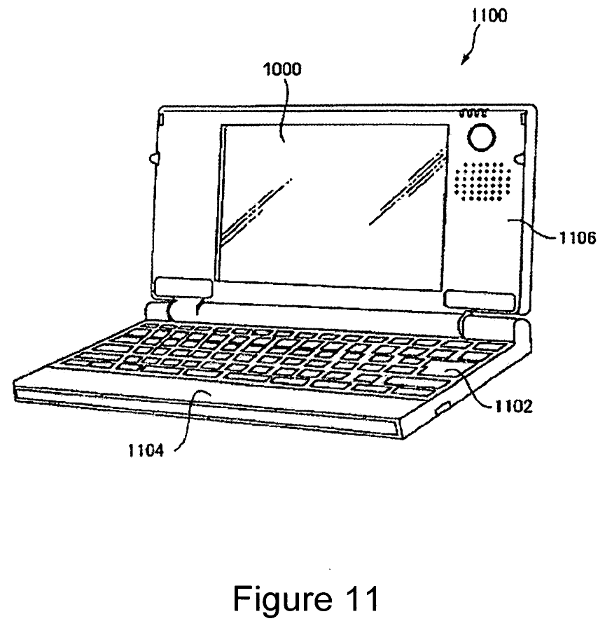

FIG. 11 is an oblique view of the structure of a portable (or notebook) personal computer to which the electronic device as an embodiment of the invention.

In FIG. 1, a personal computer 1100 includes a main unit 1104 equipped with a keyboard 1102, and a display unit 1106. The display unit 1106 is supported such that it can be rotated with respect to the main unit 1104 via a hinge structure.

The display unit 1106 of this personal computer 1100 is equipped with an image display device 1000.

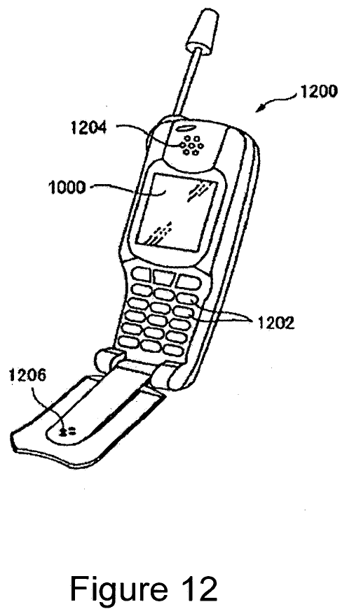

FIG. 12 is an oblique view of the structure of a portable telephone (including a PHS) to which the electronic device as an embodiment of the invention.

In FIG. 12, a portable telephone 1200 includes a plurality of control buttons 1202, an earpiece 1204, a mouthpiece 1206, and the image display device 1000.

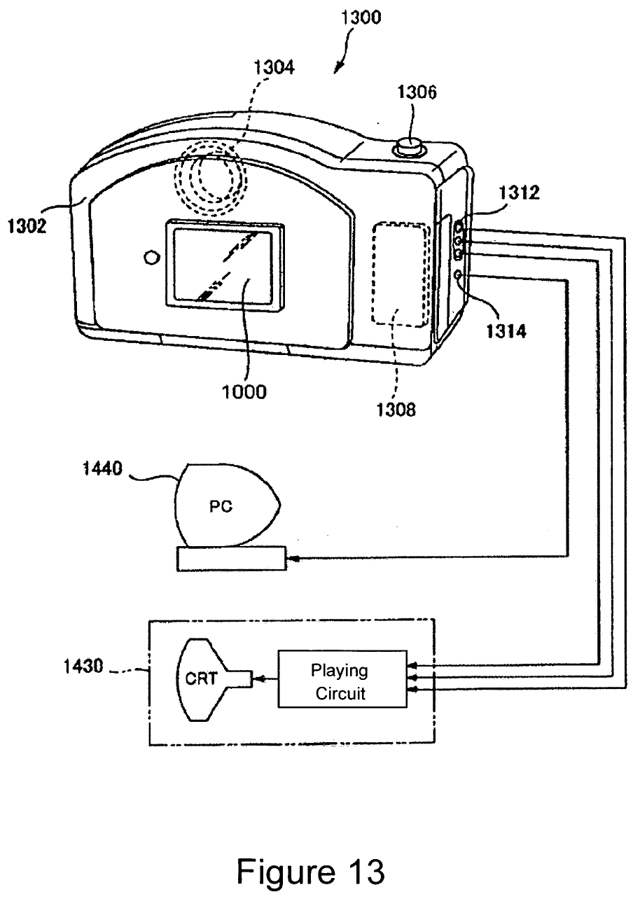

FIG. 13 is an oblique view of the structure of a digital still camera to which the electronic device as an embodiment the invention. This drawing also shows the simplified connections to external devices.

Whereas an ordinary camera uses light from the subject to expose a silver halide photographic film, the digital still camera 1300 produces an image signal by subjecting light from the subject to opto-electric conversion with a CCD (Charge Coupled Device) or other such image capturing element.

The image display device 1000 is provided to the display component on the back of a case (housing) 1302 of the digital still camera 1300, performs display on the basis of the image signals from the CCD, and functions as a finder in which the subject is displayed as an electronic image.

A circuit board 1308 is installed in the case. This circuit board 1308 is furnished with a memory in which the image signals can be stored.

A light receiving unit 1304 that includes an optical lens (image capturing optical system), CCD, or the like is provided on the front side of the case 1302 (the back side in the view shown in FIG. 13).

The user checks the subject image displayed in the display component and presses a shutter button 1306, whereupon the image signal from the CCD at that instant is transferred to and stored in the memory of the circuit board 1308.

Also, with the digital still camera 1300, a video signal output terminal 1312 and a data communication input/output terminal 1314 are provided on the side of the case 1302. As shown in the drawing, a monitor 1430 is connected to the video signal output terminal 1312, and a personal computer 1440 to the data communication input/output terminal 1314, as needed. The user operates the controls so that the image signals stored in the memory of the circuit board 1308 are outputted to the monitor 1430 or the personal computer 1440.

In addition to the above-mentioned personal computers (portable personal computers), portable telephones, and digital still cameras, the electronic device of the invention can also be applied to television sets, video cameras, viewfinder type and monitor (direct view) type video tape recorders, laptop personal computers, car navigation units, pagers, electronic notebooks (including those equipped with a communications function), electronic dictionaries, calculators, electronic game devices, word processors, work stations, video phones, security television monitors, electronic microscopes, POS terminals, devices equipped with a touch panel (such as vending machines and cash dispensers of financial institutions), medical devices (such as electronic thermometers, blood pressure gauges, blood sugar testers, electrocardiogram display devices, ultrasound diagnostic devices, endoscope display devices), fish finders, various kinds of measurement device, gauges (such as automotive, aeronautic, and marine gauges), flight simulators, various other kinds of monitor, projectors and other such projection display devices, and so forth.

Embodiments of the droplet discharge apparatus, panel manufacturing method, image display device, and electronic device of the invention were described above, but the invention is not limited to these. The various components that make up the droplet discharge apparatus can be replaced with components of another structure capable of exhibiting the same function. Other structures may also be added.

For instance, in the bank formation step in the above-mentioned method for manufacturing a color element film-equipped substrate, the effect of the invention will be the same if the third layer is omitted, the first layer and then the second layer are laminated on the supporting substrate, parts of the first and second layers are removed through exposure and developing, and the remainders thereof are used as banks.

This application claims priority to Japanese Patent Application No. 2004-375703. The entire disclosure of Japanese Patent Application No. 2004-375703 is hereby incorporated herein by reference.

What is claimed is:

1. A method for manufacturing a color element film-equipped substrate, comprising:
forming a bank, in which a first layer and a photo-curing second layer are laminated over a base, and parts of the first layer and the second layer are removed after exposing and developing the first layer and the second layer, with a remainder of the first layer and the second layer serving as a bank;
applying a liquid material used for forming a color element film to a region demarcated by the bank; and
forming a color element film by curing or solidifying the liquid material applied to the region,
wherein the first layer is soluble in a developing liquid during the developing, the second layer is soluble in the developing liquid but dissolves in the developing liquid more slowly than the first layer does, and the bank is formed with a width of the remainder of the second layer being greater than a width of the remainder of the first layer after the developing.

2. The method for manufacturing a color element film-equipped substrate according to claim 1, wherein
the second layer contains a photoresist material.

3. The method for manufacturing a color element film-equipped substrate according to claim 2, wherein,
in forming the bank, prior to the exposure, a photo-curing third layer is formed on a side of the second layer opposite from the first layer.

4. The method for manufacturing a color element film-equipped substrate according to claim 3, wherein
the second layer is a mixture of the material constituting the first layer and the material constituting the third layer.

5. The method for manufacturing a color element film-equipped substrate according to claim 4, wherein
a width of a portion of the second layer that will be cured by the exposure during the forming of the bank is greater than a width of a portion of the third layer that will be cured by the exposure during the forming of the bank.

6. The method for manufacturing a color element film-equipped substrate according to claim 4, wherein
the third layer repels the liquid material.

7. The method for manufacturing a color element film-equipped substrate according to claim 1, wherein
the first layer blocks light.

8. A color element film-equipped substrate, manufactured by the method for manufacturing a color element film-equipped substrate according to claim 1.

9. A color element film-equipped substrate comprising
a base;
a bank provided over the base; and
a color element film formed in a region demarcated by the bank,
wherein the bank has a protruding component that protrudes toward an inside of the region, at a point along a height of the bank.

10. The color element film-equipped substrate according to claim 9, wherein the protruding component is formed over substantially the entire periphery of the region.

11. The color element film-equipped substrate according to claim 9, wherein the bank narrows in width above and below the protruding component.

12. An electro-optical device, furnished with the color element film-equipped substrate according to claim 1.

13. An electronic device, furnished with the electro-optical device according to claim 12.
